(19) United States
(12) Patent Application Publication
(10) Pub. No.: US 2017/0301705 A1
(43) Pub. Date: Oct. 19, 2017

(54) LTPS PIXEL UNIT AND MANUFACTURING METHOD FOR THE SAME

(71) Applicant: SHENZHEN CHINA STAR OPTOELECTRONICS TECHNOLOGY CO., LTD., Shenzhen, Guangdong (CN)

(72) Inventors: Yutong HU, Shenzhen, Guangdong (CN); Peng DU, Shenzhen, Guangdong (CN)

(73) Assignee: Shenzhen China Star Optoelectronics Technology Co., Ltd., Shenzhen, Guangdong (CN)

(21) Appl. No.: 14/426,187

(22) PCT Filed: Dec. 29, 2014
(86) PCT No.: PCT/CN2014/095385

§ 371 Date: Mar. 5, 2015

(30) Foreign Application Priority Data
Dec. 12, 2014 (CN) 201410768769.8

(51) Int. Cl. H01L 27/12; H01L 29/786

(52) U.S. Cl. CPC H01L 27/1288; H01L 29/78675; H01L 29/78633; H01L 27/1222; H01L 27/127; H01L 27/124; H01L 29/78621

(57) ABSTRACT

An LTPS pixel unit and a manufacturing method. The method includes following steps: forming a buffering layer on the substrate; forming a semiconductor pattern and a common electrode pattern which are disposed with an interval on the buffering layer; sequentially forming a first insulation layer, a gate electrode pattern and a second insulation layer on the semiconductor pattern; forming a source electrode pattern and a drain electrode pattern on the second insulation layer, wherein, the source electrode pattern and the drain electrode pattern electrically contact with the semiconductor pattern through a first contact hole at the first insulation layer and the second insulation layer; and forming a pixel electrode pattern on the second insulation layer, wherein, the pixel electrode pattern electrically contacts with the source electrode pattern or the drain electrode pattern. Accordingly, the present invention can save the cost and increase process yield.

### BACKGROUND OF THE INVENTION

### 1. Field of the Invention

The present invention relates to a display technology field, and more particularly to an LTPS pixel unit and a manufacturing method for the same.

### 2. Description of Related Art

In a small size and high-resolution display, an LTPS (Low Temperature Poly-Silicon) display has been widely used due to the high mobility, stable performance characteristics.

A conventional pixel unit of the LTPS display has many layers and structures, and is very complicated to manufacture. Using conventional NMOS manufacturing process as an example, 10 mask processes are required. The specific elements using the mask processes are respectively: a light shielding pattern, a semiconductor pattern, a doped semiconductor pattern, a gate electrode pattern, a first conductive hole for a first and a second insulation layers, a source electrode pattern and a drain electrode pattern, an organic layer pattern, a capacitor electrode pattern, a passivation layer pattern, and a pixel electrode pattern. As a result, the production cost is large.

Besides, in the pixel unit of the conventional LTPS display, the organic layer pattern is used for decreasing the load of a driving circuit. Accordingly, the organic layer pattern is required to be thick such that the uniformity of the production is hard to guarantee. As a result, the mura phenomenon (uneven of the brightness of the display) is formed so as to reduce the product yield.

### SUMMARY OF THE INVENTION

The technology problem solved by the present invention is to provide an LTPS pixel unit and a manufacturing method for the same. The present invention can save manufacturing process in order to decrease the cost. A thicker organic layer is also omitted in order improve the product yield.

In order to solve the above problem, a technology solution adopted by the present invention is: a manufacturing method for a low temperature poly-silicon (LTPS) pixel unit, comprising: providing a substrate; forming a buffering layer on the substrate; forming a semiconductor pattern and a common electrode pattern which are disposed with an interval on the buffering layer; sequentially forming a first insulation layer, a gate electrode pattern and a second insulation layer on the semiconductor pattern, wherein, the gate electrode pattern is disposed right above the semiconductor pattern; the first insulation layer and the second insulation layer cover the common electrode pattern; forming a source electrode pattern and a drain electrode pattern on the second insulation layer, wherein, the source electrode pattern and the drain electrode pattern electrically contact with the semiconductor pattern through a first contact hole at the first insulation layer and the second insulation layer; and forming a pixel electrode pattern on the second insulation layer, wherein, the pixel electrode pattern electrically contacts with the source electrode pattern or the drain electrode pattern.

Wherein, before the step of forming a buffering layer on the substrate, further comprising a step of forming a light shielding pattern on the substrate, wherein, the semiconductor pattern is disposed right above the light shielding pattern.

Wherein, in the step of forming the light shielding pattern on the substrate comprises: forming a light shielding layer on the substrate; and through a first mask process to pattern the light shielding layer in order to form the light shielding pattern; wherein, in the step of forming the semiconductor pattern and the common electrode pattern which are disposed with an interval on the buffering layer comprises: depositing an amorphous silicon layer on the buffering layer, and patterning the amorphous silicon layer through a second mask process in order to form the semiconductor pattern; forming an intrinsic region and a heavily doped region located at both sides of the intrinsic region through a third mask process and a first doping process on the semiconductor pattern; and forming a first conductive layer on the buffering layer and the semiconductor pattern, and patterning the first conductive layer through a fourth mask process in order to form the common electrode pattern.

Wherein, in the step of sequentially forming a first insulation layer, a gate electrode pattern and a second insulation layer on the semiconductor pattern comprises: forming a second conductive layer on the first insulation layer; and patterning the second conductive layer through a fifth mask process in order to form the gate electrode pattern, wherein, the gate electrode pattern is located right above the intrinsic region.

Wherein, in the step of sequentially forming a first insulation layer, a gate electrode pattern and a second insulation layer on the semiconductor pattern, further comprises a step of using the gate electrode pattern as a mask pattern, and adopting a self-alignment method and a second doping process to form a lightly doped region between the intrinsic region and the heavily doped region in the semiconductor pattern.

Wherein, in the step of forming a pixel electrode pattern on the second insulation layer comprises: forming the first contact hole at a location of the first insulation layer and the second insulation layer corresponding to the heavily doped region through a sixth mask process; forming a third conductive layer on the second insulation layer, and patterning the third conductive layer through a seventh mask process in order to form the source electrode pattern and the drain electrode pattern corresponding to a location of the first contact hole; and wherein, in the step of forming a pixel electrode pattern on the second insulation layer comprises: forming a fourth conductive layer on the second insulation layer, the source electrode pattern and the drain electrode pattern; patterning the fourth conductive layer through an eighth mask process in order to form the pixel electrode pattern.

Wherein, in the step of forming a pixel electrode pattern on the second insulation layer comprises: forming a second contact hole corresponding to the common electrode pattern through the sixth mask process; and patterning the third conductive layer through a seventh mask process in order to form a conductive pattern which is electrically connected with the common electrode pattern at a location of the second contact hole.

In order to solve the above problem, another technology solution adopted by the present invention is: a low temperature poly-silicon (LTPS) pixel unit, comprising: a substrate; a light shielding pattern and a buffering layer sequentially disposed on the substrate; a semiconductor pattern and a common electrode pattern which are disposed with an interval on the buffering layer; a first insulation layer, a gate electrode pattern and a second insulation layer sequentially formed on the semiconductor pattern, wherein, the gate electrode pattern is disposed right above the semiconductor pattern; the first insulation layer and the second insulation layer cover the common electrode pattern; a source electrode pattern and a drain electrode pattern, a conductive pattern disposed on the second insulation layer, wherein, the source electrode pattern and the drain electrode pattern electrically contact with the semiconductor pattern through a first contact hole at the first insulation layer and the second insulation layer; the conductive pattern is electrically connected with the common electrode pattern through a second contact hole at the first insulation layer and the second insulation layer; and a pixel electrode pattern formed on the second insulation layer, wherein, the pixel electrode pattern electrically contacts with the source electrode pattern or the drain electrode pattern.

Wherein, the LTPS pixel unit further comprises a passivation layer disposed on the pixel electrode pattern.

Wherein, the semiconductor pattern is formed by an intrinsic region, a heavily doped region and a lightly doped region, wherein, the gate electrode pattern is disposed right above the intrinsic region; the heavily doped region is disposed at both sides of the intrinsic region; the lightly doped region is located between the intrinsic region and the heavily doped region.

Wherein, the pixel electrode pattern and the common electrode pattern are made of indium tin oxide (ITO).

In order to solve the above problem, another technology solution adopted by the present invention is: a low temperature poly-silicon (LTPS) pixel unit, comprising: a substrate; a light shielding pattern and a buffering layer sequentially disposed on the substrate; a semiconductor pattern and a common electrode pattern which are disposed with an interval on the buffering layer; a first insulation layer, a gate electrode pattern and a second insulation layer sequentially formed on the semiconductor pattern, wherein, the gate electrode pattern is disposed right above the semiconductor pattern; the first insulation layer and the second insulation layer cover the common electrode pattern; a source electrode pattern and a drain electrode pattern, a conductive pattern disposed on the second insulation layer, wherein, the source electrode pattern and the drain electrode pattern electrically contact with the semiconductor pattern through a first contact hole at the first insulation layer and the second insulation layer; the conductive pattern is electrically connected with the common electrode pattern through a second contact hole at the first insulation layer and the second insulation layer; a pixel electrode pattern formed on the second insulation layer, wherein, the pixel electrode pattern electrically contacts with the source electrode pattern or the drain electrode pattern; and a passivation layer disposed on the pixel electrode pattern; wherein, the semiconductor pattern is formed by an intrinsic region, a heavily doped region and a lightly doped region, wherein, the gate electrode pattern is disposed right above the intrinsic region; the heavily doped region is disposed at both sides of the intrinsic region; the lightly doped region is located between the intrinsic region and the heavily doped region.

Wherein, the pixel electrode pattern and the common electrode pattern are made of indium tin oxide (ITO).

The beneficial effect of the present invention is: comparing to the prior art, through forming a semiconductor pattern and a common electrode pattern which are disposed with an interval on ae buffering layer; sequentially forming a first insulation layer, a gate electrode pattern and a second insulation layer on the semiconductor pattern, wherein, the gate electrode pattern is disposed right above the semiconductor pattern; the first insulation layer and the second insulation layer cover the common electrode pattern; forming a source electrode pattern and a drain electrode pattern on the second insulation layer, wherein, the source electrode pattern and the drain electrode pattern electrically contact with the semiconductor pattern through a first contact hole at the first insulation layer and the second insulation layer; and forming a pixel electrode pattern on the second insulation layer, wherein, the pixel electrode pattern electrically contacts with the source electrode pattern or the drain electrode pattern. Accordingly, the present invention can save the manufacturing processes in order to save the cost, and omit the thicker organic layer in order to improve product yield.

### BRIEF DESCRIPTION OF THE DRAWINGS

FIG. 1 is a flowchart of a manufacturing method for an LTPS pixel unit according to an embodiment of the present invention;

FIG. 2 is a manufacturing diagram corresponding to the method shown in FIG. 1; and

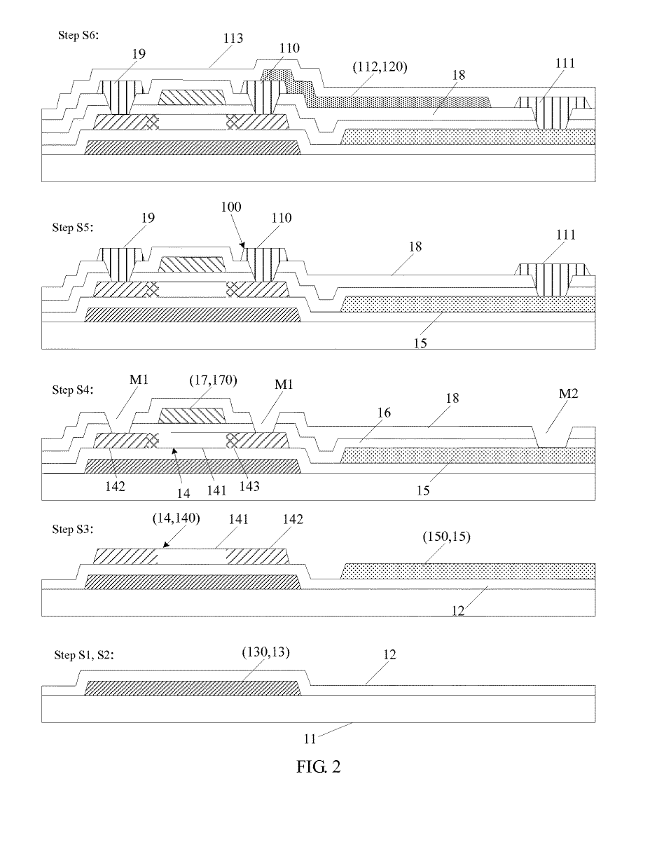

FIG. 3 is a structural schematic diagram of an LTPS pixel unit according to an embodiment of the present invention.

### DETAILED DESCRIPTION OF THE PREFERRED EMBODIMENT

The following will combine drawings and embodiments for detailed description of the present invention.

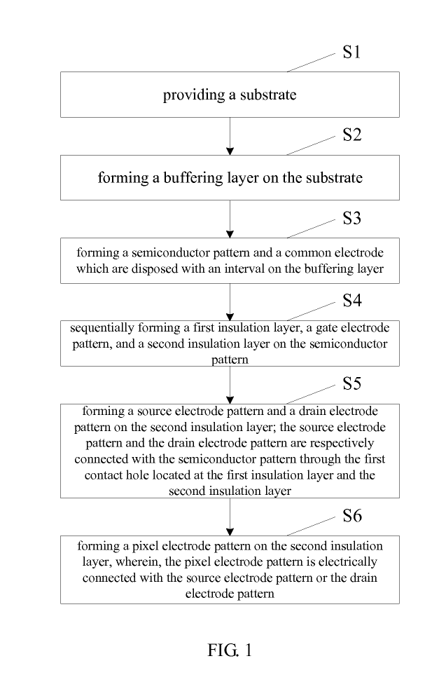

With reference to FIG. 1, FIG. 1 is a flowchart of a manufacturing method for an LTPS pixel unit according to an embodiment of the present invention. The manufacturing method of the LTPS pixel unit of the present invention including following steps:

Step S1: providing a substrate 11.

Wherein, the substrate 11 is preferably a glass substrate. When providing the substrate 11, cleaning, sanding and other operations to remove impurities on the surface of the substrate 11 at the same time. Then, through a drying step to dry the substrate 11 so as to provide a clean substrate 11.

Step S2: forming a buffering layer 12 on the substrate 11.

Before step S2, forming a light shielding pattern 13 on the substrate 11. The light shielding pattern 13 is specifically made of a metal material or an amorphous silicon material.

The specific manufacturing process of the light shielding pattern 13 is: forming a light shielding layer 130 on the substrate 11; through a first mask process to pattern the light shielding layer 130 in order to form the light shielding pattern 13.

Wherein, the first mask process is specifically: forming a photoresist on the light shielding layer 130, exposing and developing the photoresist to reveal a portion of the substrate 11 which is outside the light shielding pattern 13; Then, removing the photoresist on the light shielding pattern 13 in order to obtain the light shielding pattern 13.

Wherein, the later mask processes without special description can adopt the mask process in the present step. The present invention does not limit the operation principle of the mask.

In this step, the buffering layer 12 is specifically formed by using CVD (Chemical Vapor Deposition). Notably, the buffering layer 12 is a structure having an entire surface, and the buffering layer 12 does not require a mask process to be patterned.

Step S3: forming a semiconductor pattern 14 and a common electrode 15 which are disposed with an interval on the buffering layer 12.

Wherein, specifically, the step of forming a semiconductor pattern 14 is: depositing an amorphous silicon layer 140 on the buffering layer 12, and then, performing an excimer laser annealing (ELA) to complete crystallization. Then, patterning the amorphous silicon layer 140 through a second mask process in order to form the semiconductor pattern 14. Wherein, the semiconductor pattern 14 is located right above the light shielding pattern 13.

Furthermore, after forming the semiconductor pattern 14, forming an intrinsic region 141 and a heavily doped region 142 located at both sides of the intrinsic region 141 through a third mask process and a first doping process on the semiconductor pattern 14.

Wherein, the heavily doped region 142 is formed through an ion implantation method to perform an N+ heavily doping at the heavily doped region 142. The heavily doped region 142 can form an ohmic contact with a source electrode and a drain electrode formed subsequently.

In the present step, the specific manufacturing process for the common electrode pattern is: forming a first conductive layer 150 on the buffering layer 12 and the semiconductor pattern 14, and patterning the first conductive layer 150 through a fourth mask process in order to form the common electrode pattern 15.

Wherein the common electrode pattern 15 is made of ITO (Indium tin oxide, a transparent conductive film). In another embodiment, the common electrode pattern 15 can also be formed by another conductive material.

In the present embodiment, the common electrode pattern 15 and the semiconductor pattern 14 are disposed at a same layer and are disposed on the buffering layer 12 such that an organic layer used for separating the common electrode pattern 15, the source electrode, and the drain electrode can be omitted in order to reduce the material cost and reduce the manufacturing process.

Step S4: sequentially forming a first insulation layer 16, a gate electrode pattern 17, and a second insulation layer 18 on the semiconductor pattern 14. Wherein, the gate electrode pattern 17 is disposed right above the semiconductor pattern 14; the first insulation layer 16 and the second insulation layer 18 further cover the common electrode pattern 15.

In this step, the ways for forming the first insulation layer 16 and the second insulation layer 18 are the same. Both utilize a CVD method for deposition. Each of the first insulation layer 16 and the second insulation layer 18 is a structure having an entire surface. No mask process is required.

Wherein, the specific manufacturing process for forming the gate electrode pattern 17 is: forming a second conductive layer 170 on the first insulation layer 16; patterning the second conductive layer 170 through a fifth mask process in order to form the gate electrode pattern 17. The gate electrode pattern 17 is located right above the intrinsic region 141.

After completing the gate electrode pattern 17, using the gate electrode pattern 17 as a mask pattern and adopting a self-alignment method and a second doping process to form a lightly doped region 143 between the intrinsic region 141 and the heavily doped region 143 in the semiconductor pattern 14.

Wherein, the lightly doped region 143 is formed by using an N− lightly doping method at that region.

In the present step, after forming the second insulation layer 18, forming a first contact hole M1 at a location of the first insulation layer 16 and the second insulation layer 18 which is corresponding to the heavily doped region 142 of the semiconductor pattern 14. The specific forming process is: forming the first contact hole M1 at the location of the first insulation layer 16 and the second insulation layer 18 which is corresponding to the heavily doped region 142 of the semiconductor pattern 14 through a sixth mask process.

Furthermore, a second contact hole M2 can also be formed at a location corresponding to the common electrode pattern 15 through the sixth mask process. It can be understood that the formation of the first contact hole M1 and the second contact hole M2 can also be performed in a step S5.

Therefore, in the present step, the first contact hole M1 and the second contact hole M2 can be formed by the same mask process. Comparing to the art for manufacturing the conventional LTPS pixel unit, one mask process is omitted so as to reduce the cost.

Step S5: forming a source electrode pattern 19 and a drain electrode pattern 110 on the second insulation layer 18. The source electrode pattern 19 and the drain electrode pattern 110 are respectively connected with the semiconductor pattern 14 through the first contact hole M1 located at the first insulation layer 16 and the second insulation layer 18.

In the present step, when forming the source electrode pattern 19 and the drain electrode pattern 110, a conductive pattern 111 will also be formed at the same time.

The specific process for forming the source electrode pattern 19, the drain electrode pattern 110, and the conductive pattern 111 is: further forming a third conductive layer 100 on the second insulation layer 18, and patterning the third conductive layer 100 through a seventh mask process in order to respectively form the source electrode pattern 19 and the drain electrode pattern 110 which are corresponding to a location of the first contact hole Ml, and to form the conductive pattern 111 which is electrically connected with the common electrode pattern 15 at a location of the second contact hole M2.

Step S6: forming a pixel electrode pattern 112 on the second insulation layer 18, wherein, the pixel electrode pattern 112 is electrically connected with the source electrode pattern 19 or the drain electrode pattern 110.

Wherein, the specific forming process of the pixel electrode pattern 112 is: forming a fourth conductive layer 120 on the conductive pattern 111, the second insulation layer 18, the source electrode pattern 19, and the drain electrode pattern 110; patterning the fourth conductive layer 120 through an eighth mask process in order to form the pixel electrode pattern 112.

In the present embodiment, the pixel electrode pattern 112 is formed on the second insulation layer 18 such that the pixel electrode pattern 112, the source electrode pattern 19 and the source electrode pattern 110 are disposed at the same layer. As a result, the pixel electrode pattern 112 can electrically connect with the source electrode pattern 19 or the source electrode pattern 110 without a mask process to form a conductive hole. The present invention can further reduce one mask process in order to save the cost.

Wherein, the pixel electrode pattern 112 is formed by an ITO material.

In the present embodiment, a passivation layer 113 is further formed on the pixel electrode pattern 112. The passivation layer 113 can be formed through the CVD method, and the passivation layer 113 is a structure having an entire surface such that the passivation layer 113 does not require a mask process. The passivation layer 113 can effectively protect the traces on the substrate 11.

In this embodiment, only eight mask processes are required to manufacture the LTPS pixel unit. Comparing to the conventional art, the conventional LTPS requires ten mask processes. The present invention reduces two mask processes in order to save the manufacture cost.

Furthermore, the present invention reduces the organic layer in the conventional LTPS pixel unit such that the uniformity requirement of the process is decreased so as to prevent the mura phenomenon and increase the process yield.

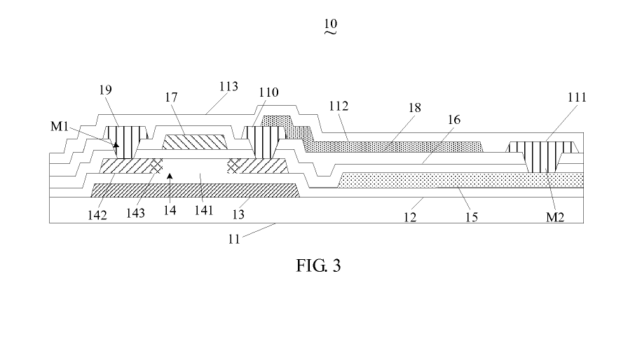

With reference to FIG. 3, FIG. 3 is a structural schematic diagram of an LTPS pixel unit according to an embodiment of the present invention. Wherein, the LTPS pixel unit 10 is manufactured by the method described above. As shown in FIG. 3, the LTPS pixel unit 10 of the present embodiment includes a substrate 11, a light shielding pattern 13, a buffering layer 12, a semiconductor pattern 14, a common electrode pattern 15, a first insulation layer 16, a gate electrode pattern 17, a second insulation layer 18, a source electrode pattern 19, a drain electrode pattern 110, a conductive pattern 111, and a pixel electrode pattern 112. Wherein, the substrate 11 is a glass substrate.

The light shielding pattern 13 and the buffering layer 12 are sequentially disposed on the substrate 11. Wherein, the buffering layer 12 is a structure having an entire surface. The light shielding pattern 13 is made of a metal material or an amorphous silicon material.

The semiconductor pattern 14 and the common electrode pattern 15 are disposed on the buffering layer 12 with an interval. Wherein, the semiconductor pattern 14 is disposed right above the light shielding pattern 13. The semiconductor pattern 14 is specifically formed by an intrinsic region 141, a heavily doped region 142, and a lightly doped region 143. Wherein, the heavily doped region 142 is located at both sides of the intrinsic region 141. The lightly doped region 143 is located between the heavily doped regions 142. The heavily doped region 142 is formed by performing an N+ heavily doping. The lightly doped region 143 is formed by performing an N− lightly doping. The common electrode 150 is made of an ITO material.

The first insulation layer 16, the gate electrode pattern 17 and the second insulation layer 18 are sequentially disposed on the semiconductor pattern 14. Wherein, the gate electrode pattern 17 is located right above the semiconductor pattern 14. Specifically, the gate electrode pattern 17 is located right above the intrinsic region 141 of the semiconductor pattern 14. The first insulation layer 16 and the second insulation layer 18 further covers the common electrode pattern 15 such that the common electrode 15, the source electrode pattern 19 and the drain electrode pattern 110 are isolated by the first insulation layer 16 and the second insulation layer 18. As a result, the parasitic capacitance between the common electrode pattern 15, the source electrode pattern 19 and the drain electrode pattern 110 can be effectively decreased to lower the circuit load. At the same time, the organic layer of the conventional LTPS pixel unit is omitted in order to decrease the uniformity requirement of the manufacture process, prevent mura phenomenon, and increase process yield.

The source electrode pattern 19, the drain electrode pattern 110 and conductive pattern 111 are disposed on the second insulation layer 18. Wherein, the source electrode pattern 19 and the drain electrode pattern 110 are respectively electrically connected with the semiconductor pattern 14 through the first contact hole M1 at the first insulation layer 16 and the second insulation layer 18. The conductive pattern 111 is electrically connected with the common electrode pattern 15 through the second contact hole M2 at the first insulation layer 16 and the second insulation layer 18.

A pixel electrode pattern 112 is disposed on the second insulation layer 18. Wherein, the pixel electrode pattern 112 is electrically connected with the source electrode pattern 19 or the drain electrode pattern 110. The pixel electrode pattern 112, the source electrode pattern 19 and the drain electrode pattern 110 are disposed at the same layer. Therefore, the pixel electrode pattern 112 can directly and electrically connect with the source electrode pattern 19 or the drain electrode pattern 110. No mask process for forming a conductive hole is required so as to reduce the mask processes, and the cost.

In this embodiment, the LTPS pixel unit 10 further includes a passivation layer 113 disposed on the pixel electrode pattern 112, and the passivation layer 113 covers the source electrode 19, a portion of the drain electrode 110 which is not covered by the pixel electrode pattern 112, the second insulation layer 18, and the conductive pattern 111. Therefore, the circuit traces on the substrate 11 are effectively protected.

In summary, the LTPS pixel unit of the present invention not only saves two mask processes, but also saves the organic layer so that the manufacturing cost and material cost are reduced in order to prevent mura, increase the process yield.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A manufacturing method for a low temperature poly-silicon (LTPS) pixel unit, comprising:
providing a substrate;
forming a buffering layer on the substrate;
forming a semiconductor pattern and a common electrode pattern which are disposed with an interval on the buffering layer;
sequentially forming a first insulation layer, a gate electrode pattern and a second insulation layer on the semiconductor pattern, wherein, the gate electrode pattern is disposed right above the semiconductor pattern; the first insulation layer and the second insulation layer cover the common electrode pattern;
forming a source electrode pattern and a drain electrode pattern on the second insulation layer, wherein, the source electrode pattern and the drain electrode pattern electrically contact with the semiconductor pattern through a first contact hole at the first insulation layer and the second insulation layer; and
forming a pixel electrode pattern on the second insulation layer, wherein, the pixel electrode pattern electrically contacts with the source electrode pattern or the drain electrode pattern.

2. The manufacturing method according to claim 1, wherein, before the step of forming a buffering layer on the substrate, the method further comprises a step of forming a light shielding pattern on the substrate, wherein, the semiconductor pattern is disposed right above the light shielding pattern.

3. The manufacturing method according to claim 2,
wherein, in the step of forming the light shielding pattern on the substrate comprises:
forming a light shielding layer on the substrate; and
patterning the light shielding layer through a first mask process in order to form the light shielding pattern;
wherein, in the step of forming the semiconductor pattern and the common electrode pattern which are disposed with an interval on the buffering layer comprises:
depositing an amorphous silicon layer on the buffering layer, and patterning the amorphous silicon layer through a second mask process in order to form the semiconductor pattern;
forming an intrinsic region and a heavily doped region located at both sides of the intrinsic region through a third mask process and a first doping process on the semiconductor pattern; and
forming a first conductive layer on the buffering layer and the semiconductor pattern, and patterning the first conductive layer through a fourth mask process in order to form the common electrode pattern.

4. The manufacturing method according to claim 3, wherein, in the step of sequentially forming a first insulation layer, a gate electrode pattern and a second insulation layer on the semiconductor pattern comprises:
forming a second conductive layer on the first insulation layer; and
patterning the second conductive layer through a fifth mask process in order to form the gate electrode pattern, wherein, the gate electrode pattern is located right above the intrinsic region.

5. The manufacturing method according to claim 4, wherein, in the step of sequentially forming a first insulation layer, a gate electrode pattern and a second insulation layer on the semiconductor pattern, further comprises a step of using the gate electrode pattern as a mask pattern, and adopting a self-alignment method and a second doping process to form a lightly doped region between the intrinsic region and the heavily doped region in the semiconductor pattern.

6. The manufacturing method according to claim 4, wherein, in the step of forming a pixel electrode pattern on the second insulation layer comprises:
forming the first contact hole at a location of the first insulation layer and the second insulation layer corresponding to the heavily doped region through a sixth mask process;
forming a third conductive layer on the second insulation layer, and patterning the third conductive layer through a seventh mask process in order to form the source electrode pattern and the drain electrode pattern corresponding to a location of the first contact hole; and
wherein, in the step of forming a pixel electrode pattern on the second insulation layer comprises:
forming a fourth conductive layer on the second insulation layer, the source electrode pattern and the drain electrode pattern; patterning the fourth conductive layer through an eighth mask process in order to form the pixel electrode pattern.

7. The manufacturing method according to claim 6, wherein, in the step of forming a pixel electrode pattern on the second insulation layer comprises:
forming a second contact hole corresponding to the common electrode pattern through the sixth mask process; and
patterning the third conductive layer through a seventh mask process in order to form a conductive pattern which is electrically connected with the common electrode pattern at a location of the second contact hole.

8. A low temperature poly-silicon (LTPS) pixel unit, comprising:
a substrate;
a light shielding pattern and a buffering layer sequentially disposed on the substrate;
a semiconductor pattern and a common electrode pattern which are disposed with an interval on the buffering layer;
a first insulation layer, a gate electrode pattern and a second insulation layer sequentially formed on the semiconductor pattern, wherein, the gate electrode pattern is disposed right above the semiconductor pattern; the first insulation layer and the second insulation layer cover the common electrode pattern;
a source electrode pattern and a drain electrode pattern, a conductive pattern disposed on the second insulation layer, wherein, the source electrode pattern and the drain electrode pattern electrically contact with the semiconductor pattern through a first contact hole at the first insulation layer and the second insulation layer; the conductive pattern is electrically connected with the common electrode pattern through a second contact hole at the first insulation layer and the second insulation layer; and
a pixel electrode pattern formed on the second insulation layer, wherein, the pixel electrode pattern electrically contacts with the source electrode pattern or the drain electrode pattern.

9. The LTPS pixel unit according to claim 8, wherein, the LTPS pixel unit further comprises a passivation layer disposed on the pixel electrode pattern.

10. The LTPS pixel unit according to claim 8, wherein, the semiconductor pattern is formed by an intrinsic region, a heavily doped region and a lightly doped region, wherein, the gate electrode pattern is disposed right above the intrinsic region; the heavily doped region is disposed at both sides of the intrinsic region; the lightly doped region is located between the intrinsic region and the heavily doped region.

11. The LTPS pixel unit according to claim 8, wherein, the pixel electrode pattern and the common electrode pattern are made of indium tin oxide (ITO).

12. A low temperature poly-silicon (LTPS) pixel unit, comprising:
a substrate;
a light shielding pattern and a buffering layer sequentially disposed on the substrate;
a semiconductor pattern and a common electrode pattern which are disposed with an interval on the buffering layer;
a first insulation layer, a gate electrode pattern and a second insulation layer sequentially formed on the semiconductor pattern, wherein, the gate electrode pattern is disposed right above the semiconductor pattern; the first insulation layer and the second insulation layer cover the common electrode pattern;
a source electrode pattern, a drain electrode pattern and a conductive pattern disposed on the second insulation layer, wherein, the source electrode pattern and the drain electrode pattern electrically contact with the semiconductor pattern through a first contact hole at the first insulation layer and the second insulation layer; the conductive pattern is electrically connected with the common electrode pattern through a second contact hole at the first insulation layer and the second insulation layer;
a pixel electrode pattern formed on the second insulation layer, wherein, the pixel electrode pattern electrically contacts with the source electrode pattern or the drain electrode pattern; and
a passivation layer disposed on the pixel electrode pattern;
wherein, the semiconductor pattern is formed by an intrinsic region, a heavily doped region and a lightly doped region, wherein, the gate electrode pattern is disposed right above the intrinsic region; the heavily doped region is disposed at both sides of the intrinsic region; the lightly doped region is located between the intrinsic region and the heavily doped region.

13. The LTPS pixel unit according to claim 12, wherein, the pixel electrode pattern and the common electrode pattern are made of indium tin oxide (ITO).
